(19) United States
(12) Patent Application Publication
(10) Pub. No.: US 2021/0311391 A1
(43) Pub. Date: Oct. 7, 2021

(54) PHOTOSENSITIVE RESIN COMPOSITION, METHOD FOR FORMING RESIST PATTERN, METHOD FOR MANUFACTURING PLATED FORMED BODY, AND SEMICONDUCTOR DEVICE

(71) Applicant: JSR CORPORATION, Tokyo (JP)

(72) Inventors: Takuhiro TANIGUCHI, Tokyo (JP); Naoki NISHIGUCHI, Tokyo (JP); Tomoyuki MATSUMOTO, Tokyo (JP); Hirokazu SAKAKIBARA, Tokyo (JP); Akito HIRO, Tokyo (JP); Hisanori AKIMARU, Tokyo (JP)

(73) Assignee: JSR CORPORATION, Tokyo (JP)

(21) Appl. No.: 17/268,998

(22) PCT Filed: Jul. 1, 2019
(86) PCT No.: PCT/JP2019/026193

§ 371 Date: Feb. 17, 2021

(30) Foreign Application Priority Data
Aug. 21, 2018 (JP) 2018-155044

(51) Int. Cl. G03F 7/039; G03F 7/004; C08F 220/30

(52) U.S. Cl. CPC G03F 7/039; C08F 220/301; G03F 7/0045

(57) ABSTRACT

The present photosensitive resin composition includes a polymer (A) having a structural unit (a1) represented by a formula (a1), a structural unit (a2) represented by a formula (a2), and a structural unit (a3) represented by a formula (a3) and a photoacid generator (B). In the formulae (a1) to (a3), R¹¹, R²¹, and R³¹ each independently represent a hydrogen atom, a substituted or non-substituted alkyl group having 1 to 10 carbon atom or a halogen atom; R¹² and R³² each independently represent a divalent organic group; R²² represents a substituted or non-substituted alkanediyl group having 2 to 10 carbon atoms; R¹³ represents an acid dissociable group having an alicyclic structure; R²³ represents an alkyl group having 1 to 10 carbon atoms; R³³ represents a hydroxyaryl group; and 1, m and n each independently represent an integer from 0 to 10.

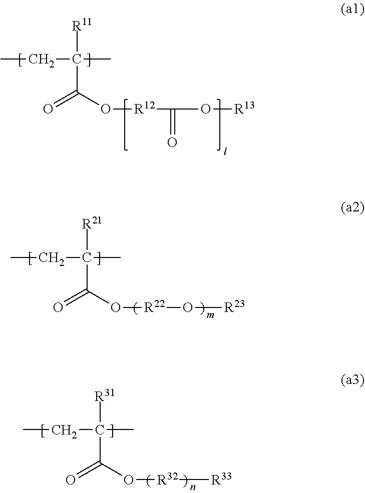

### TECHNICAL FIELD

The present invention relates to a photosensitive resin composition, a method for forming a resist pattern, a method for manufacturing a plated formed article, and a semiconductor device.

### BACKGROUND ART

Since elements such as semiconductor elements and display elements are required to be mounted at high density, circuit boards are manufactured through wafer-level processing of wiring, connection terminals, sealing resin and the like, in which a processing that has conventionally been performed after cutting out chips from wafers is performed before cutting out chips from wafers. In the wafer-level processing, wiring, connection terminals, and the like are generally formed by a technique (photofabrication) of preparing a coating of a resist composition on a substrate such as a wafer by rotary coating (spin coating) and exposing/developing the coating to prepare a resist, and using the resist as a mold to perform a plating process.

It is known that, when a coating of a resist composition is formed on a substrate by spin coating, there are problems that the coating bulges on the peripheral edge of the substrate and that the resist composition leaks to the back surface of the substrate. In order to remove the bulging coating and the resist composition leaking to the back surface, an EBR (Edge Bead Removal) processing, i.e., a processing which involves discharging a solvent onto the peripheral edge and back surface of the substrate during spin coating to remove the bulging coating and the resist composition leaking to the back surface, is performed.

### PRIOR TECHNICAL ART

### Patent Literature

Patent Literature 1: JP 2008-243945 A

### SUMMARY OF INVENTION

### Technical Problems

An object of the present disclosure is to provide a photosensitive resin composition that forms a resist pattern useful as a mold for a plating process, that is, to provide a photosensitive resin composition that has excellent resolution in order to cope with miniaturization of wiring and connection terminals, can form a resist pattern having excellent plating solution resistance in order to cope with a plating process, and further, when formed as a coating, does not remain undissolved on a peripheral edge of a substrate after the EBR processing.

Additionally, an object of the present disclosure is to provide a method for forming a resist pattern using the photosensitive resin composition, to provide a method for manufacturing a plated formed article using a resist pattern formed by the resist pattern forming method, and to provide a semiconductor device using a plated formed article obtained by the plated formed article manufacturing method.

### Solutions to Problems

The present disclosure contains, for example, the following contents [1] to [12].

[1] A photosensitive resin composition including: a polymer (A) having a structural unit (a1) represented by the following formula (a1), a structural unit (a2) represented by the following formula (a2), and a structural unit (a3) represented by the following formula (a3); and a photoacid generator (B).

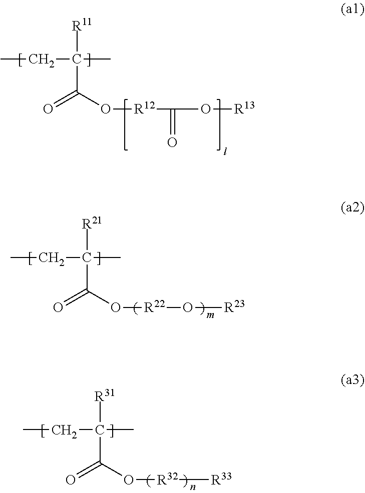

(In the formulae (a1) to (a3), R¹¹, R²¹, and R³¹ each independently represent a hydrogen atom, a substituted or non-substituted alkyl group having 1 to 10 carbon atom or a halogen atom; R¹² and R³² each independently represent a divalent organic group; R²² represents a substituted or non-substituted alkanediyl group having 2 to 10 carbon atoms; R¹³ represents an acid dissociable group having an alicyclic structure; R²³ represents an alkyl group having 1 to 10 carbon atoms; R³³ represents a hydroxyaryl group; and 1, m and n each independently represent an integer from 0 to 10.)

[2] The photosensitive resin composition according to [1] above, wherein a content ratio of the structural unit (a2) contained in the polymer (A) is in a range from 1% to 50% by mol when a total of all the structural units constituting the polymer (A) is 100% by mol.

[3] The photosensitive resin composition according to [1] or [2] above, wherein a total content ratio of the structural units (a1) and (a3) contained in the polymer (A) is in a range from 50% to 95% by mol when a total of all the structural units constituting the polymer (A) is 100% by mol.

[4] The photosensitive resin composition according to any one of [1] to [3] above, wherein the R¹³ is an acid dissociable group represented by the following formula (1).

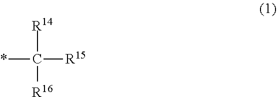

(In the formula (1), R¹⁴ and R¹⁵ form an alicyclic structure together with the bonded carbon atom; R¹⁶ represents a substituted or non-substituted alkyl group having 1 to 10 carbon atoms; and * represents a bonded hand.)

[5] The photosensitive resin composition according to any one of [1] to [4] above, wherein a total content ratio of the structural units (a1) to (a3) contained in the polymer (A) is in a range from 51% to 100% by mol when a total of all the structural units constituting the polymer (A) is 100% by mol.

[6] The photosensitive resin composition according to any one of [1] to [5] above, wherein a content of the photoacid generator (B) included in the photosensitive resin composition is in a range from 0.1 to 20 parts by mass based on 100 parts by mass of the polymer (A).

[⁷] The photosensitive resin composition according to any one of [1] to [6] above, further including an organic solvent (C), wherein a content ratio of the organic solvent (C) included in the photosensitive resin composition is an amount such that a solid content concentration is in a range from 10% to 60% by mass.

[8] The photosensitive resin composition according to any one of [1] to [7], which is used for manufacturing a plated formed article.

[9] A method for forming a resist pattern including:

a step (1) of applying the photosensitive resin composition according to any one of [1] to [8] above onto a substrate to form a resin coat;

a step (2) of exposing the resin coat to light; and

a step (3) of developing the resin coat after the exposure.

[10] A method for manufacturing a plated formed article including a step (4) of performing a plating using a resist pattern formed by the resist pattern forming method according to [9] above as a mask.

[11] The method for manufacturing a plated formed article according to [10] above, wherein the plating is at least one selected from a copper plating and a nickel plating.

[12] A semiconductor device including a plated formed article obtained by the plated formed article manufacturing method according to [10] or [11] above.

### Advantageous Effects of Invention

When the photosensitive resin composition of the present disclosure is used, a coating of the photosensitive resin composition does not remain undissolved on a peripheral edge of a substrate after the EBR processing, excellent resolution can be obtained, and a resist pattern having excellent plating solution resistance in order to cope with a plating process can be obtained.

### DESCRIPTION OF EMBODIMENTS

Hereinafter, the photosensitive resin composition (hereinafter, also referred to as “the present composition”), the method for forming a resist pattern, the method for manufacturing a plated molded article, and the semiconductor device according to the present disclosure, will be described in detail.

For each of the components exemplified herein, for example, each of the components in the photosensitive resin composition and each of the structural units in the polymer (A), only one type thereof may be contained, or two or more types thereof may be contained, unless otherwise specified.

### 1. Photosensitive Resin Composition

The present composition includes a polymer (A) having a structural unit (a1) represented by the formula (a1), a structural unit (a2) represented by the formula (a2), and a structural unit (a3) represented by the formula (a3); and a photoacid generator (B).

In addition, the present composition may include an organic solvent (C), a quencher (D) and a surfactant (E), and any other component, if needed, as long as the effects of the present composition are not impaired.

### Polymer (A)

The polymer (A) has the structural unit (a1) having an acid dissociable group, the structural unit (a2), and the structural unit (a3).

The polymer (A) may have, in addition to the structural units (a1) to (a3), a structural unit (hereinafter, also referred to as “structural unit (a4)”) having a group that promotes solubility in an alkaline developer (hereinafter, also referred to as “solubility promoting group”) other than the structural unit (a3), a structural unit (hereinafter, also referred to as “structural unit (a5)”) having an acid dissociable group other than the structural unit (a1), and other structural unit (hereinafter, also referred to as “structural unit (a6)”).

The structural units (a1) to (a3) may be contained in the same polymer or different polymers, but the structural units (a1) to (3) are preferably contained in the same polymer. For the polymer (A), only one type thereof or two or more types thereof may be contained.

The polymer (A) has an acid dissociable group in the structural unit (a1). The acid dissociable group dissociates by a function of an acid generated from the photoacid generator (B). As a result, a carboxy group is generated, the solubility of the polymer (A) in an alkaline developer changes, and the present composition can form a resist pattern.

In general, the resolution of the photosensitive resin composition for forming a thick-film resist pattern can be improved by increasing the rate of dissolution in the alkaline developer after dissociation of the acid dissociable groups of the acid dissociable group-containing polymer contained in the photosensitive resin composition. On the other hand, increasing the rate of dissolution in an alkaline developer reduces the solubility in a solvent (hereinafter, also referred to as “EBR solvent”) used in an EBR processing, and thus, a resin coating of the photosensitive resin composition tends to remain undissolved on a peripheral edge of a substrate after the EBR processing.

The polymer (A) contained in the composition of the present disclosure has the structural unit (a3) for a purpose of increasing the rate of dissolution in an alkaline developer, and the structural unit (a2) for a purpose of improving the solubility in an EBR solvent. It is inferred that the presence of the structural units (a2) and (a3) in the polymer (A) makes it possible to increase the rate of dissolution in an alkaline developer and to improve the solubility in an EBR solvent, and, as a result, that the photosensitive resin composition has excellent resolution, and a formed resin coating does not remain undissolved on a peripheral edge of a substrate after the EBR processing.

It is considered that, when the solubility of the polymer in the photosensitive resin composition in an organic solvent such as the EBR solvent is improved, an organic solvent contained in a plating solution easily permeates a mask in a plating process using the resist pattern formed therefrom, leading to a problem that the resist pattern swells during the plating process. However, if the polymer has the structural units (a2) and (a3) like the polymer (A), the penetration of the organic solvent contained in the plating solution to the mask can be suppressed. It is inferred that, as a result, a photosensitive resin composition capable of forming a resist pattern having excellent plating solution resistance is obtained.

The “structural units” described in the specification represent structures derived from monomers used in synthesis of the polymer. For example, as a monomer (al′) serving as the structural unit (a1), a monomer having a polymerizable unsaturated double bond, which is represented by the following formula (a1′), is exemplified.

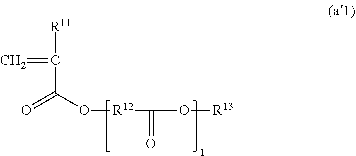

In the formula (a1′), R¹¹, R¹², R¹³, and 1 are synonymous with R¹¹, R¹², R¹³, and 1, respectively, in the formula (a1).

### Structural Unit (a1)

The structural unit (a1) is a structural unit represented by the following formula (a1) and is one including an acid dissociable group having an alicyclic structure.

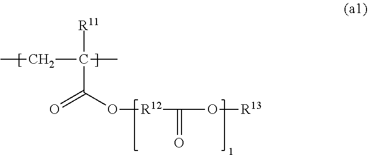

In the formula (a1), represents a hydrogen atom, a substituted or non-substituted alkyl group having 1 to 10 carbon atoms, or a halogen atom; R¹² represents a divalent organic group; R¹³ represents an acid dissociable group having an alicyclic structure; and 1 represents an integer of 0 to 5, and preferably an integer of 0 to 3.

Examples of the halogen atom as include a fluorine atom, a chlorine atom, a bromine atom, an iodine atom, and the like.

Examples of the substituted or non-substituted alkyl group having 1 to 10 carbon atoms as R¹¹ include a non-substituted alkyl group such as methyl group, ethyl group, n-propyl group, isopropyl group, pentyl group and decyl group; a substituted alkyl group in which at least one hydrogen atom in the alkyl group is replaced with other group including a halogen atom such as fluorine atom and bromine atom, an aryl group such as phenyl group, a hydroxyl group, and an alkoxy group.

Examples of the divalent organic group having 1 to 10 carbon atoms as R¹² include an alkanediyl group such as methylene group, ethylene group, propane-1,3-diyl group, propane-1,2-diyl group, and decane-1,10-diyl group; and a group in which at least one hydrogen atom in the alkanediyl group is replaced with other group such as a halogen atom including fluorine atom and bromine atom, an aryl group such as phenyl group, hydroxyl group, and alkoxy group.

Examples of the acid dissociable group having an alicyclic structure as R¹³ include an acid dissociable group represented by the following formula (1), and a tertiary alkyl group such as a 1-alkylcyclopentan-1-yl group and a 2-alkyladamantan-2-yl group. Among these, the acid dissociable group represented by the formula (1) is preferable since a coating of the photosensitive resin composition of the present disclosure does not remain undissolved on a peripheral edge of a substrate after the EBR processing, has excellent resolution, and can form a resist pattern having excellent plating solution resistance in order to cope with a plating process.

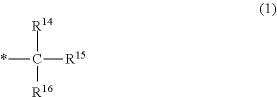

In the formula (1), R¹⁴ and R¹⁵ form an alicyclic structure with a carbon atom bonded to R¹⁴ and R¹⁵; R¹⁶ represents a substituted or non-substituted alkyl group having 1 to 10 carbon atoms; and * represents a bond.

Examples of the alicyclic structure composed of R¹⁴, R¹⁵ and the carbon atom include a monocyclic saturated cyclic hydrocarbon structure such as cyclobutyl, cyclopentyl, cyclohexyl, cycloheptyl and cyclooctyl; a monocyclic unsaturated cyclic hydrocarbon structure such as cyclobutenyl, cyclopentenyl and cyclohexenyl; and a polycyclic saturated cyclic hydrocarbon structure such as norbornyl, adamantyl, tricyclodecyl and tetracyclododecyl.

Among these, a monocyclic saturated cyclic hydrocarbon structure is preferable.

Examples of the substituted or non-substituted alkyl group having 1 to 10 carbon atoms as R¹⁶ include a non-substituted alkyl group such as methyl group, ethyl group, n-propyl group, isopropyl group, pentyl group and decyl group; a substituted alkyl group in which at least one hydrogen atom in the alkyl group is replaced with other group including a halogen atom such as fluorine atom and bromine atom, an aryl group such as phenyl group, a hydroxyl group, and an alkoxy group.

Examples of the structural unit (a1) include structural units represented by the following chemical formulae.

In the following chemical formulae, R¹¹ is synonymous with R¹¹ in the above formula (a1).

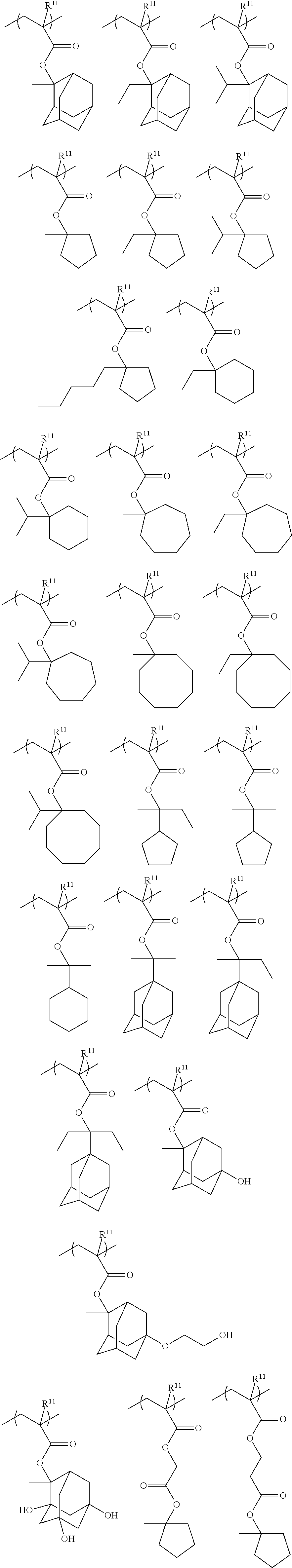

One or more types of the structural unit (a1) may be contained in the polymer (A).

A content ratio of the structural unit (a1) contained in the polymer (A) is in a range from 1% to 55% by mol when a total of all the structural units constituting the polymer (A) is 100% by mol. A lower limit thereof is 1% by mol, preferably 2% by mol, and more preferably 5% by mol, and an upper limit thereof is 55% by mol, preferably 50% by mol, and more preferably 45% by mol. Further, any combination of the upper and lower limits of the content ratio of the structural unit (a1) can be used.

When the content ratio of the structural unit (a1) included in the polymer (A) falls within the range described above, a coating of the photosensitive resin composition does not remain undissolved on a peripheral edge of a substrate after the EBR processing, excellent resolution can be obtained, and a resist pattern having excellent plating solution resistance in order to cope with a plating process can be obtained.

### Structural Unit (a2)

The structural unit (a2) is a structural unit represented by the following formula (a2). The presence of the structural unit (a2) in the polymer (A) makes it possible to improve the solubility of the polymer (A) in the EBR solvent.

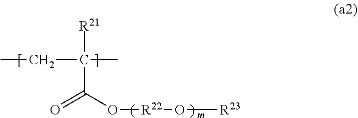

In the formula (a2), R²¹ represents a hydrogen atom, a substituted or non-substituted alkyl group having 1 to 10 carbon atoms, or a halogen atom; R²² represents a substituted or non-substituted alkanediyl group having 2 to 10 carbon atoms; R²³ represents an alkyl group having 1 to 10 carbon atoms; and m indicates an integer of 0 to 10.

Examples of the substituted or non-substituted alkyl group having 1 to 10 carbon atoms as R²¹ include the groups exemplified as the substituted or non-substituted alkyl group having 1 to 10 carbon atoms as R¹¹.

Examples of the substituted or non-substituted alkanediyl group having 2 to 10 carbon atoms as R²² include a non-substituted alkanediyl group such as ethylene group, propane-1,3-diyl group, propane-1,2-diyl group, butane-1,4-diyl group, pentane-1,5-diyl group, hexane-1,6-diyl group, heptane-1,7-diyl group, octane-1,8-diyl group, nonane-1,9-diyl group, decane-1,10-diyl group, dodecane-1,12-diyl group, tetradecane-1,14-diyl group, heptadecane-1,17-diyl group, ethane-1,1-diyl group, propane-1,1-diyl group, propane-2,2-diyl group, butane-1,3-diyl group, 2-methylpropane-1,3-diyl group, 2-methylpropane-1,2-diyl group, pentane-1,4-diyl group and 2-methylbutane-1,4-diyl group; and a substituted alkanediyl group in which at least one hydrogen atom in the alkanediyl group is replaced with other groups including a halogen atom such as fluorine atom and bromine atom, an aryl group such as phenyl group, hydroxyl group, and alkoxy group.

The number of the carbon atoms of the substituted or non-substituted alkanediyl group having 2 to 10 carbon atoms as R²² is preferably in a range from 2 to 5.

m is preferably in a range from 0 to 4, and more preferably from 0 to 1.

Examples of the alkyl group having 1 to 10 carbon atoms as R²³ include methyl group, ethyl group, n-propyl group, isopropyl group, pentyl group, and decyl group.

The number of the carbon atoms of the alkyl group having 1 to 10 carbon atoms as R²³ is preferably in a range from 1 to 6, and more preferably from 1 to 4.

Examples of the monomer (a2′) leading to the structural unit (a2) include 2-methoxyethyl (meth)acrylate, n-butyl (meth)acrylate, ethyl (meth)acrylate, isopropyl (meth)acrylate, n-dodecyl (meth)acrylate, 2-methoxybutyl (meth)acrylate, lauroxytetraethylene glycol (meth)acrylate, lauroxydipropylene glycol (meth)acrylate, lauroxytripropylene glycol (meth)acrylate, and lauroxytetrapropylene glycol (meth)acrylate.

One or more types of the structural unit (a2) may be contained in the polymer (A).

A content ratio of the structural unit (a2) contained in the polymer (A) is in a range from 1% to 50% by mol when a total of all the structural units constituting the polymer (A) is 100% by mol. A lower limit thereof is 1% by mol, preferably 2% by mol, and more preferably 5% by mol, and an upper limit thereof is 50% by mol, preferably 45% by mol, and more preferably 40% by mol. Further, any combination of the upper and lower limits of the content ratio of the structural unit (a2) can be used.

When the content ratio of the structural unit (a2) included in the polymer (A) falls within the range described above, a coating of the photosensitive resin composition does not remain undissolved on a peripheral edge of a substrate after the EBR processing, excellent resolution can be obtained, and a resist pattern having excellent plating solution resistance in order to cope with a plating process can be obtained.

### Structural Unit (a3)

The structural unit (a3) is a structural unit represented by the following formula (a3) and has a hydroxyaryl group which is a solubility promoting group. The presence of the structural unit (a3) in the polymer (A) makes it possible to improve the resolution in a thick film of the composition, and to improve the solubility of the polymer (A) in the EBR solvent without swelling the resist pattern during plating.

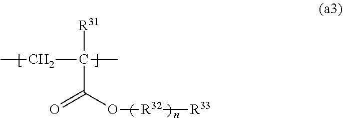

In the formula (a3), R³¹ represents a hydrogen atom, a substituted or non-substituted alkyl group having 1 to 10 carbon atoms, or a halogen atom; R³² represents an organic group having 1 to 10 carbon atoms; R³³ represents a hydroxyaryl group; n represents an integer from 0 to 10.

Examples of the substituted or non-substituted alkyl group having 1 to 10 carbon atoms as R³¹ include the groups exemplified as the substituted or non-substituted alkyl group having 1 to 10 carbon atoms as R¹¹.

Examples of the hydroxyaryl group as R³³ include a hydroxyphenyl group such as 2-hydroxyphenyl group, 3-hydroxyphenyl group, 4-hydroxyphenyl group, 3-methyl-4-hydroxyphenyl group, trihydroxyphenyl group, tetrahydroxyphenyl group, dihydroxybiphenyl group, and hydroxybenzenecarbonyl groups; a hydroxynaphthyl group such as hydroxynaphthyl group, dihydroxynaphthyl group, and hydroxynaphthalenecarbonyl group; and a hydroxyanthryl group such as hydroxyanthracenecarbonyl group.

Among these, the hydroxyphenyl group can form a resist pattern having excellent plating solution resistance because it is compatible with plating. Further, the hydroxyphenyl group leads to a coating of the photosensitive resin composition which does not remain undissolved on a peripheral edge of a substrate after the EBR processing,

A preferable structure of the structural unit (a3) is, for example, a structural unit (a31) represented by the following formula (a31).

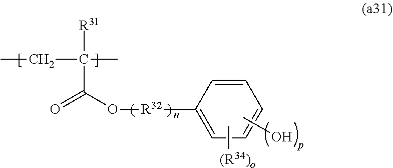

In the formula (a31), R³¹, R³² and n are synonymous with R³¹, R³² and n of the structural unit (a3); R³⁴ is attached to the benzene ring, representing a halogen atom, an alkyl group or an aryl group; —OH is bonded to the benzene ring; o indicates an integer of 0 to 4; p indicates an integer of 1 to 5; and a relationship o+p=5 is satisfied.

Examples of a monomer leading to the structural unit (a31) include a monomer (a31′) represented by the following formula (a31′).

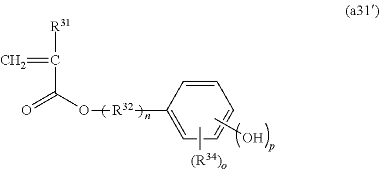

In the formula (a31′), R³¹, R³², n, R³⁴, o, and p are synonymous with R³¹, R³², and n in the structural unit (a3), and R³⁴, o, and p in the formula (a31), respectively.

One or more types of the structural unit (a3) may be contained in the polymer (A).

A content ratio of the structural unit (a3) contained in the polymer (A) is in a range from 15% to 80% by mol when a total of all the structural units constituting the polymer (A) is 100% by mol. A lower limit thereof is 15% by mol, preferably 20% by mol, and more preferably 25% by mol, and an upper limit thereof is 80% by mol, preferably 75% by mol, and more preferably 70% by mol, Further, any combination of the upper and lower limits of the content ratio of the structural unit (a3) can be used.

A ratio of total contents of the structural units (a1) and (a3) contained in the polymer (A) is in a range from 50% to 95% by mol, when a total of all the structural units constituting the polymer (A) is 100% by mol. A lower limit thereof is 50% by mol, preferably 60% by mol, and more preferably 65% by mnol, and an upper limit thereof is 95% by mol, preferably 90% by mol, and more preferably 85% by mol. Further, any combination of the upper and lower limits of the total content ratio of the structural units (a1) and (a3) can be used.

When the content ratio of the structural unit (a3) included in the polymer (A) falls within the range described above, a coating of the photosensitive resin composition does not remain undissolved on a peripheral edge of a substrate after the EBR processing, excellent resolution can be obtained, and a resist pattern having excellent plating solution resistance in order to cope with a plating process can be obtained.

A ratio of total contents of the structural units (a1) to (a3) contained in the polymer (A) is in a range from 51% to 100% by mol, when a total of all the structural units constituting the polymer (A) is 100% by mol. A lower limit thereof is 51% by mol, preferably 55% by mol, and more preferably 60% by mol, and an upper limit thereof is 100% by mol, preferably 95% by mol, and more preferably 90% by mol. Further, any combination of the upper and lower limits of the total content ratio of the structural units (a1) to (a3) can be used.

When the total content ratio of the structural units (a1) to (a3) included in the polymer (A) falls within the range described above, a coating of the photosensitive resin composition does not remain undissolved on a peripheral edge of a substrate after the EBR processing, excellent resolution can be obtained, and a resist pattern having excellent plating solution resistance in order to cope with a plating process can be obtained.

### Structural Unit (a4)

The structural unit (a4) is a structural unit having a solubility promoting group other than the structural unit (a3). The presence of the structural unit (a4) in the polymer (A) makes it possible to adjust the resolution, sensitivity, depth of focus, exposure latitude, and other lithographic properties to a resin coating formed from the present composition.

Examples of the structural unit (a4) include a structural unit having a carboxy group, a hydroxyaryl group, a hydroxy group, a lactone structure, a cyclic carbonate structure, a sultone structure, or a fluoroalcohol structure. Among these, a structural unit having a hydroxyaryl group is preferable because the resist pattern formed from the present composition is resistant to pushing from the plating at the time of forming a plated formed article.

Examples of the structural unit having a carboxy group include a structural unit derived from a monomer such as (meth)acrylic acid, crotonic acid, maleic acid, fumaric acid, cinnamic acid, 2-carboxyethyl (meth)acrylate, 2-carboxypropyl (meth)acrylate, and 3-carboxypropyl (meth)acrylate.

Examples of the structural unit having a hydroxyaryl group include a structural unit derived from a vinyl-based monomer such as 2-hydroxystyrene, 4-hydroxystyrene, 4-isopropenylphenol, 4-hydroxy-1-vinylnaphthalene, and 4-hydroxy-2-vinylnaphthalene.

Examples of the structural unit having a hydroxy group include a structural unit derived from a monomer such as 2-hydroxyethyl (meth)acrylate and 3-(meth)acryloyloxy-4-hydroxytetrahydrofuran, and structural units described in paragraph [0030] of JP 2009-276607 A.

Examples of the structural unit having a lactone structure include structural units described in paragraphs [0104] to [0107] of JP 2017-058421 A, structural units described in paragraph [0028] of WO 2009/113228, structural units described in paragraphs [0133] to [0134] of JP 2010-138330 A, structural units described in paragraphs [0064], [0093] and [0095] of JP 2010275555 A, structural units derived from the monomer described in paragraph [0019] of JP 2016-098350 A, and structural units derived from the monomers described in paragraphs [0017] to [0023] of JP 2015-214634 A.

Examples of the structural unit having a cyclic carbonate structure include structural units described in paragraphs [0105] to [0106] of JP 2017-058421 A, structural units derived from the monomers described in paragraphs [0034] of JP 2009-223294 A, and structural units derived from the monomers described in paragraph [0092] of JP 2017-044875 A.

Examples of the structural unit having a sultone structure include structural units described in paragraph [0106] of JP 2017-058421 A, structural units described in paragraphs [0024] to [0028] of JP 2014-029518 A, structural units described in paragraphs [0033] and [0036] of JP 2016-061933 A, and structural unit described in paragraph [0087] of JP 2013-007846 A.

Examples of the structural unit having a fluoroalcohol structure include structural units derived from the monomers described in paragraphs [0066], [0069] and [0071] of JP 2004-083900 A, structural unit described in paragraph [0023] of JP 2003-002925 A, structural units described in paragraphs [0043], [0045], and [0047] of JP 2004-145048 A, and structural units derived from the monomers described in paragraph [0034] of JP 2005-133066 A.

In addition, the structural units described in the known documents indicated above shall be described herein.

A content ratio of a total of the structural units (a3) and (a4) contained in the polymer (A) is usually in a range from 10% to 80% by mol, when a total of all the structural units constituting the polymer (A) is 100% by mol.

### Structural Unit (a5)

The structural unit (a5) is a structural unit having an acid dissociable group other than the structural unit (a1). The presence of the structural unit (a5) in the polymer (A) makes it possible to adjust the resolution, sensitivity, depth of focus, exposure latitude, and other lithographic properties to a resin coating formed from the present composition.

Examples of the structural unit (a5) include structural units derived from t-butyl (meth)acrylate and benzyl (meth)acrylate; structural units having an acetal-based acid dissociable group described in paragraphs [0038] to [0040], and [0051] to [0043] of JP 2005-208366 A; and structural units having a crosslinked acid dissociable group derived from the monomers described in paragraphs [0027] to [0033] of JP 2000-214587 A.

The structural units described in the known documents indicated above shall be described herein.

A content ratio of a total of the structural units (a1) and (a5) contained in the polymer (A) is usually in a range from 5% to 60% by mol, when a total of all the structural units constituting the polymer (A) is 100% by mol.

### Structural Unit (a6)

The structural unit (a6) is a structural unit other than the structural units (a1) to (a4).

Examples of the structural unit (a6) include a structural unit derived from a vinyl compound such as styrene, 2-methylstyrene, 3-methylstyrene, 4-methylstyrene, 2-methoxystyrene, 3-methoxystyrene, and 4-methoxystyrene;

a structural unit derived from an aliphatic (meth)acrylic acid ester compound such as methyl (meth)acrylate, ethyl (meth)acrylate, n-pentyl (meth)acrylate, neopentyl (meth)acrylate, n-hexyl (meth)acrylate, and 2-ethylhexyl (meth)acrylate;

a structural unit derived from an alicyclic (meth)acrylic acid ester compound such as cyclopentyl (meth)acrylate, norbornyl (meth)acrylate, isobornyl (meth)acrylate, tricyclodecanyl (meth)acrylate, dicyclopentenyl (meth)acrylate, tetrahydrofuranyl (meth)acrylate, and tetrahydropyranyl (meth)acrylate;

a structural unit derived from an aromatic-containing (meth)acrylic acid ester compound such as phenyl (meth)acrylate and phenethyl (meth)acrylate; a structural unit derived from an unsaturated nitrile compound such as (meth)acrylonitrile, crotononitrile, maleinitrile, and fumaronitrile;

a structural unit derived from unsaturated amide compound such as (meth)acrylamide and N,N-dimethyl (meth)acrylamide; and a structural unit derived from an unsaturated imide compound such as maleimide, N-phenylmaleimide, and N-cyclohexylmaleimide.

A content ratio of the structural unit (a6) contained in the polymer (A) is usually 40% or less by mol, when a total of all the structural units constituting the polymer (A) is 100% by mol.

Production Method of Polymer (A)

The polymer (A) can be produced by polymerizing the monomers leading to the respective structural units by a publicly known polymerization method such as ionic polymerization method and radical polymerization method. From a viewpoint of mass productivity, it is preferable to produce the polymer (A) by radical polymerization method among these methods.

Examples of a radical polymerization initiator used in the radical polymerization method include an azo compound such as 2,2′-azobisisobutyronitrile and 2,2′-azobis-(2,4-dimethylvaleronitrile); an organic peroxide such as benzoyl peroxide, lauryl peroxide, and t-butyl peroxide; and the like.

A solvent used in the radical polymerization method is not particularly limited as long as it dissolves the produced polymer (A) but not react with the monomer components. Example thereof includes n-butyl acetate, methyl isobutyl ketone, 2-heptanone, cyclohexanone, propyleneglycol monomethylether, propyleneglycol monomethylether acetate, methyl 3-methoxypropionate, ethyl 3-ethoxypropionate, ethyl lactate, and the like. The polymerization solvent may be singly or in combination of two or more types thereof.

A weight average molecular weight (hereinafter referred to as “Mw”) of the polymer (A) in terms of polystyrene as measured by gel permeation chromatography is usually in a range from 1,000 to 500,000, preferably from 3,000 to 300,000, more preferably from 10,000 to 100,000, and further preferably from 20,000 to 60,000.

A ratio (Mw/Mn) of the Mw of the polymer (A) to a number average molecular weight (hereinafter referred to as “Mn”) of the polymer (A) in terms of polystyrene as measured by gel permeation chromatography is usually in a range from 1 to 5, and preferably from 1 to 3.

Moreover, a molecular weight regulator such as a mercaptan compound and a halogenated hydrocarbon can be used as needed when polymerizing the polymer (A) having the Mw and Mw/Mn. Photoacid generator (B)

The photoacid generator (B) is a compound that generates an acid upon exposure. The generated acid leads to dissociation of the acid dissociable groups in the polymer (A) and an acidic functional group such as carboxy group and hydroxyaryl group is formed. As a result, the exposed part of the photosensitive resin coat formed from the photosensitive resin composition becomes easily soluble in the alkaline developer, so that a positive-type resist pattern can be formed.

Examples of the photoacid generator (B) include compounds described in paragraphs [0017] to [0026], [0028] to [0039], [0042] to [0046], [0049] and [0053] of JP 2004-317907 A, compounds described in paragraphs [0090] to [0106] of JP 2014-157252 A, compounds described in paragraphs [0117] to [0123] of JP 2002-268223 A, and compounds described in paragraphs [0038] to [0041] of JP 2017-102260 A. These compounds shall be described herein.

Examples of the photoacid generator (B) include an onium salt compound such as diphenyliodonium trifluoromethanesulfonate, diphenyliodonium-p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium hexafluoroantimonate, triphenylsulfonium hexafluorophosphate, 4-t-butylphenyl/diphenylsulfonium trifluoromethanesulfonate, 4-t-butylphenyl·diphenylsulfoniumbenzenesulfonate, 4,7-di-n-butoxynaphthyl tetrahydrothiophenium trifluoromethanesulfonate, 4,7-di-n-butoxynaphthyl tetrahydrothiophenium·bis(trifluoromethanesulfonyl)imide anion, and 4,7-di-n-butoxynaphthyl tetrahydrothiophenium·tris (nonafluorobutylsulfonyl)methide;

a halogen-containing compound such as 1,10-dibromo-n-decane, 1,1-bis(4-chlorophenyl)-2,2,2-trichloroethane, phenyl-bis(trichloromethyl)-s-triazine, 4-methoxyphenyl-bis(trichloromethyl)-s-triazine, styryl-bis(trichloromethyl)-s-triazine, and naphthyl-bis(trichloromethyl)-s-triazine;

a sulfone compound such as 4-trisphenacyl sulfone, mesitylphenacyl sulfone, and bis(phenylsulfonyl)methane;

a sulfonic acid compound such as benzoin tosylate, pyrogalloltristrifluoromethanesulfonate, o-nitrobenzyltrifluoromethanesulfonate, and o-nitrobenzyl-p-toluenesulfonate; a sulfonimide compound such as N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)-4-butyl-naphthylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-ene-2,3-dicarboxyimide, N-(4-fluorophenylsulfonyloxy)bicyclo[2.1.1] heptane-5,6-oxy-2,3-dicarboxyimide, N-(4-fluorophenylsulfonyloxy)naphthylimide, and N-(10-camphor-sulfonyloxy)naphthylimide; and

a diazomethane compound such as bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl-p-toluenesulfonyldiazomethane, cyclohexylsulfonyl-1,1-dimethylethyl sulfonyldiazomethane, and bis(1,1-dimethylethylsulfonyl)diazomethane.

Among these, the onium salt compound or the sulfonimide compound are preferable because they can form a resist pattern having excellent resolution and plating solution resistance.

The photoacid generator (B) may be used singly or in combination of two or more types thereof.

A content of the photoacid generator (B) in the present composition is usually in a range from 0.1 to 20 parts by mass, preferably from 0.3 to 15 parts by mass, more preferably 0.5 to 10 parts by mass, and further preferably 1 to 5 parts by mass based on 100 parts by mass of the polymer (A). When the content of the photoacid generator (B) falls within the above range, a resist pattern which is a thick film and has excellent resolution can be obtained, and a pattern having an excellent shape can be obtained.

Organic solvent (C)

The organic solvent (C) is a component used to uniformly mix the respective components contained in the present composition.

Examples of the organic solvent (C) include an alcohol such as ethyleneglycol monomethyl ether, ethyleneglycol monoethyl ether, diethyleneglycol, diethyleneglycol monoethyl ether, ethyl lactate, and propylene glycol monomethyl ether; an ester such as ethyl acetate, ethyl 2-hydroxypropionate, ethyl 2-hydroxy-2-methylpropionate, methyl acetoacetate, and ethyl ethoxyacetate; a ketone such as methyl amyl ketone and cyclohexanone; an alkylene glycol dialkyl ether such as diethyleneglycol dimethyl ether, diethyleneglycol diethyl ether, diethyleneglycol di-n-propyl ether, and dipropyleneglycol dimethyl ether; and an alkylene glycol monoalkyl ether acetate such as ethyleneglycol monomethyl ether acetate, ethyleneglycol monoethyl ether acetate, propyleneglycol monomethyl ether acetate, propyleneglycol monoethyl ether acetate, and propyleneglycol mono-n-propyl ether acetate.

The organic solvent (C) may be used singly or in combination of two or more types thereof.

With regard to a content of the organic solvent (C) in the present composition, a lower limit of a solid content concentration is 10% by mass, preferably 20% by mass, and further preferably 25% by mass, and an upper limit thereof is 60% by mass, preferably 55% by mass, and further preferably 50% by mass. Further, any combination of the upper and lower limits of the content ratio of the organic solvent (C) can be used. Within the above range, a thick-film resist pattern can be formed satisfactorily. The solid content concentration refers to a content ratio of all the components other than the organic solvent (C) contained in the present composition.

### Quencher (D)

The quencher (D) is a component used to control the diffusion of the acid generated from the photoacid generator (B) upon exposure in the resist film, and as a result, the resolution of the present composition can be improved.

Examples of the quencher (D) include a basic compound, a compound that generates a base, and the like. Specific examples include compounds described in paragraphs [0076],[0079], and [0081] of JP 2014-013381 A, compounds described in paragraphs [0101] to [0104] of JP 2016-099483 A, and compounds described in paragraphs [0221] to [0224] of JP 2017-037320 A. These compounds shall be described herein.

Examples of the quencher (D) include an alkylamine such as n-hexylamine, n-heptylamine, di-n-butylamine, and triethylamine; an aromatic amine such as aniline and 1-naphthylamine; an alkanolamine such as triethanolamine; a polyamino compound such as ethylenediamine, 1,3-bis [144-aminophenyl)-1-methylethyl]benzene, and polyethylene imine; an amide compound such as formamide; a urea compound such as urea and methylurea; a nitrogen-containing heterocyclic compound such as imidazole and benzimidazole; and a nitrogen-containing compound having an acid dissociable group such as N-(t-butoxycarbonyl)piperidine, N-(t-butoxycarbonyl)imidazole, N-(t-butoxycarbonyl)benzimidazole, and N-(t-butoxycarbonyl)-2-phenylbenzimidazole.

The quencher (D) may be used singly or in combination of two or more types thereof.

A content of the quencher(D) contained in the present composition is usually in a range from 0.001 to 10 parts by mass based on 100 parts by mass of the polymer (A).

### Surfactant (E)

The surfactant (E) has a function of improving the coatability, defoaming property, and the like of the present composition.

A publicly known surfactant can be used as the surfactant (E). Examples of commercially available surfactant include NBX-15, FTX-204D, FTX-208D, and FTX-212D (all manufactured by Neos Co., Ltd.); BM-1100 (manufactured by BM Chemie); Megaface F142D (manufactured by Dainippon Ink and Chemicals, Inc.); Fluorad FC-135, FC-170C, FC-430, and FC-431 (all manufactured by Sumitomo 3M Ltd.); SurfIon S-112 and S-145 (both manufactured by Asahi Glass Co., Ltd.); and SH-28PA and SF-190 (both manufactured by Dow Corning Toray Silicone Co., Ltd.).

The surfactant (E) may be used singly or in combination of two or more types thereof.

A content of the surfactant (E) contained in the present composition is usually 2 parts or less by mass based on 100 parts by mass of the polymer (A).

### Other Components

Examples of other components include a sensitizer which absorbs exposure light and improves the acid generation efficiency of the photoacid generator; an alkali-soluble resin such as phenol novolac resin or poly(hydroxystyrene) and a low-molecular-weight phenol compound, which control the dissolution rate of the resin coat formed from the photosensitive resin composition in the alkaline developer; a UV absorber that blocks a photoreaction due to leakage of scattered light to the unexposed part during light exposure; a thermal polymerization inhibitor which enhances storage stability; an antioxidant; an adhesion aid; and an inorganic filler.

### Production of Photosensitive Resin Composition

The present composition can be produced by uniformly mixing the respective components. In addition, in order to remove dust, after uniform mixing of the components, the resultant mixture may be filtered through a filter or the like.

### 2. Method for Forming Resist Pattern

The method for forming a resist pattern of the present disclosure (hereinafter, referred to as “the present method for forming a resist pattern”) includes:

a step (1) of applying the present composition onto a substrate to form a resin coat;

a step (2) of exposing the resin coat to light; and

a step (3) of developing the resin coat after the exposure.

### Step (1)

The step (1) is a step of forming a resin coat of the present composition on a substrate.

Examples of the substrate include a semiconductor substrate, a glass substrate, and a substrate whose surface is provided with a various metal film and the like. A shape of the substrate is not particularly limited, and a surface shape may be flat or uneven. The shape of the substrate may be circular and square. Moreover, there is no limit on a size of the substrate.

Examples of material for the metal film include aluminum, copper, silver, gold, palladium, and an alloy containing two or more types of these metals. The metal film can be formed by a sputtering method or the like. A thickness of the metal film is usually in a range from 100 to 10,000 Å, and preferably from 500 to 2,000 Å.

Examples of a method for applying the present composition include spin coating, roll coating, screen printing, and an applicator method. Among these methods, spin coating is preferable. In the case of spin coating, a rotational speed is usually in a range from 500 to 4,000 rpm, and preferably from 800 to 3,500 rpm.

In a case of spin coating, an EBR processing is generally carried out.

In the EBR processing, for example, an EBR solvent is discharged to a resin coating on inner side of a peripheral edge by 0.1 to 10 mm on a substrate surface while rotating the substrate, during or after forming a resin coating by spin coating.

The EBR solvent may be solvents described in “solvent (C)” in “1. Photosensitive resin composition”.

In the EBR processing, an organic solvent may be discharged to a peripheral edge of the back surface of the substrate to wash the back surface thereof.

After the application of the present composition, the resin coat may be subjected to heat treatment. Conditions for the heat treatment are usually from 0.5 to 20 minutes at a temperature ranging from 50° C. to 200° C. A film thickness of the resin coat is usually in a range from 1 to 100 μm, and preferably from 5 to 80 μm.

### Step (2)

The step (2) is a step of exposing the resin coat formed in the step (1) to light.

The exposure is usually carried out selectively on the resin coat via a photomask having a predetermined mask pattern by reduced projection exposure.

A laser light having a wavelength ranging from 150 to 600 nm, preferably a laser light having a wavelength ranging from 200 to 500 nm is usually used as an exposure light.

An exposure dose may be selected depending on types of light, type of the present composition, thickness of the resin coating, or the like, and is usually in a range from 100 to 20,000 mJ/cm².

After the exposure, heat treatment can be performed. Conditions for heat treatment are usually from 1 to 10 minutes at a temperature ranging from 70° C. to 180° C.

### Step (3)

The step (3) is a step of developing the resin coat after the exposure in the step (2) to form a resist pattern.

The development is usually carried out with an alkaline developer. Examples of the developing method for the development include a shower developing method, a spray developing method, a dipping developing method, a paddle developing method, and the like. Conditions for the development are usually from 1 to 30 minutes at a temperature of 23° C.

Examples of the alkaline developer include an aqueous solution containing one or two or more types of an alkaline substance such as sodium hydroxide, potassium hydroxide, sodium carbonate, sodium silicate, ammonia water, ethylamine, n-propylamine, diethylamine, triethylamine, monoethanolamine, diethanolamine, triethanolamine, tetramethylammonium hydroxide, tetraethylammonium hydroxide, choline, pyrrole, and piperidine. The alkaline developer may contain an organic solvent such as methanol and ethanol, a surfactant, or the like.

After the development, the resist pattern may be washed with water or the like. It may then be dried with an air gun or hot plate. 3. Method for Manufacturing Plated Formed Article

The method for manufacturing a plated formed article of the present disclosure (hereinafter, also referred to as “the present method for manufacturing a plated formed article”) includes a step (hereinafter, referred to as “step (4)”) of performing a plating using a resist pattern formed by the present resist pattern forming method as a mask.

### Step (4)

In the step (4), the resist pattern formed by the resist pattern forming method is used as a mold, and a plating is carried out to form a plated formed article at an opening portion formed by the resist pattern.

Examples of the plating method include a wet plating method such as electrolytic plating, electroless plating and hot-dip plating, and a dry plating method such as chemical vapor deposition and sputtering. In wafer-level processing, wiring or a connection terminal is usually formed by electrolytic plating.

Before the electrolytic plating, pretreatment such as ashing treatment, flux treatment and desmear treatment may be performed in order to improve the affinity between an inner wall surface of the resist pattern and the plating solution.

In the case of electrolytic plating, a product formed on the inner wall of the resist pattern by sputtering or electroless plating may be used as a seed layer, and when a substrate is one whose surface is provided with a metal film, the metal film may also be used as the seed layer.

A barrier layer may be formed before the formation of the seed layer, and the seed layer may also be used as the barrier layer.

Examples of the plating solution used for the electrolytic plating include a copper plating solution containing copper sulfate, copper pyrophosphate or the like; a gold plating solution containing gold potassium cyanide; and a nickel plating solution containing nickel sulfate or nickel carbonate.

Conditions for the electrolytic plating may be appropriately selected depending on types of plating solution, and the like. For example, in a case of the electrolytic plating using copper sulfate, the temperature is usually in a range from 10° C. to 90° C. and the current density is usually in a range from 0.1 to 100 A/dm².

In the plating, different plating methods may be sequentially performed. For example, a solder copper pillar bump can be formed by first performing a copper plating, a nickel plating, and then performing a hot-dip solder plating.

A thickness of the plated formed article varies depending on its intended use. When the plated formed article is, for example, a bump, the thickness is usually in a range from 5 to 100 μm. When the plated formed article is wiring, the thickness is usually in a range from 1 to 30 μm.

Other steps

Examples of other steps in the method for manufacturing a plated formed article include a step (hereinafter, also referred to as “step (5)”) of removing the resist pattern after the step (4).

The step (5) is performed using a resist stripping solution containing tetramethyl ammonium hydroxide, dimethyl sulfoxide and/or N,N-dimethylformamide.

Further, the present method for manufacturing a plated formed article may include a step of removing a metal film in a region other than the region where the plated formed article is formed, for example, by a wet etching method.

### 4. Semiconductor Device

The semiconductor device of the present disclosure includes a plated formed article obtained by the present plated formed article manufacturing method. The present semiconductor device is provided with a plated formed article in which the resist pattern is copied through a plating process to deposit a plating component using the present resist pattern which is useful as a mold for plating process, and thus reliability is improved. Specific examples of the semiconductor device include a multilayer LSI (semiconductor integrated circuit, see http://www.jmq.jsr.co.jp/products.html).

### EXAMPLES

Hereinafter, the present invention will be described in more detail based on Examples, but is not limited thereto. In the description of the following Examples and the like, “part” is used to mean “part by mass”.

### <Method for Measuring Physical Property>

### (Method for Measuring Weight Average Molecular Weight (Mw) of Polymer)

The weight average molecular weight (Mw) of an alkali-soluble resin was measured by gel permeation chromatography method under the following conditions.

Column: Columns TSK-M and TSK2500 manufactured by Tosoh Corporation, which were connected in series

Solvent: Tetrahydrofuran

Flow rate: 0.35 mL/min

Temperature: 40° C.

Detection method: Refractive index method

Standard substance: Polystyrene

GPC device: “HLC-8220-GPC” (type name) manufactured by Tosoh Corporation

### <Production of Polymer>

### Synthesis Examples 1 to 10

Polymers (A1) to (A6) and (RA1) to (RA4) having structural units and content ratios shown in Table 1 were produced by radical polymerization using 2,2′-azobis(methyl isobutyrate) as a radical polymerization initiator. Details of the structural units shown in Table 1 are represented by the following formulae (a1-1) to (a1-3), (a2-1) to (a2-2), (a3-1), (a4-1) to (a4-2), (a5-1) to (a5-2), and (a6-1). The unit of numerical values in Table 1 is % by mol.

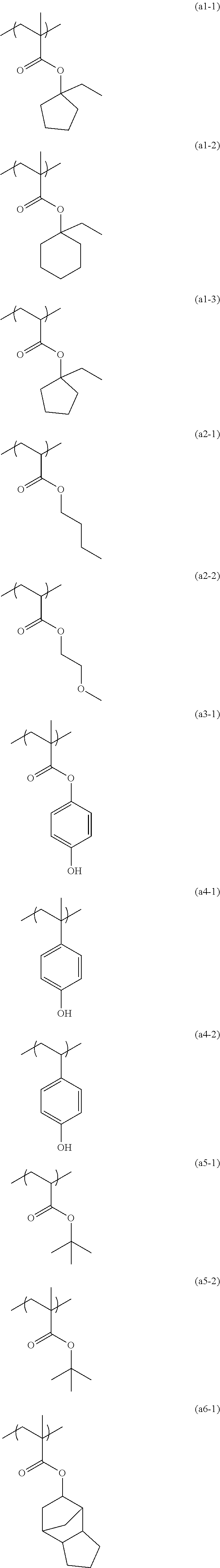

TABLE 1

| Polymer | a1-1 | a1-2 | a1-3 | a2-1 | a2-2 | a3-1 | a4-1 | a4-2 | a5-1 | a5-2 | a6-1 | Mw |
|---|---|---|---|---|---|---|---|---|---|---|---|---|
| A1 | 15 | 10 | 10 | | 15 | 50 | | | | | | 39010 |
| A2 | 15 | 10 | 10 | 20 | | 25 | 20 | | | | | 23450 |
| A3 | 15 | 10 | 10 | 15 | | 50 | | | | | | 48320 |
| A4 | 15 | | | 15 | | 40 | | 20 | 10 | | | 32330 |
| A5 | 25 | 10 | 10 | 5 | | 50 | | | | | | 35480 |
| A6 | | 5 | 10 | 15 | | 60 | | | | 10 | | 52010 |
| RA1 | 15 | 10 | 10 | | | 50 | | | | | 15 | 32400 |
| RA2 | 20 | 10 | 10 | | | 50 | | | | | 10 | 33000 |
| RA3 | 15 | | | 15 | | | 40 | 20 | 10 | | | 42050 |
| RA4 | 15 | 10 | 10 | | | | 50 | | | | 15 | 38920 |

### <Production of Photosensitive Resin Composition>

Examples 1A to 8A and Comparative Examples 1A to 4A (Production of photosensitive resin composition)

Photosensitive resin compositions of Examples 1A to 8A and Comparative Examples 1A to 4A containing types and amounts of components shown in Table 2 were produced by uniformly mixing the respective components. Details of the components, other than the polymers, shown in Table 2 are as follows. The unit of numerical values in Table 2 is part by mass.

B1: Compound having a structure represented by the following formula (B1)

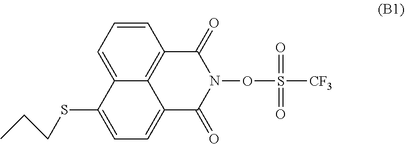 [SMILES: CCCSc1ccc2c3c(cccc13)C(=O)N(OS(=O)(=O)C(F)(F)F)C2=O]

B2: Compound having a structure represented by the following formula (B2)

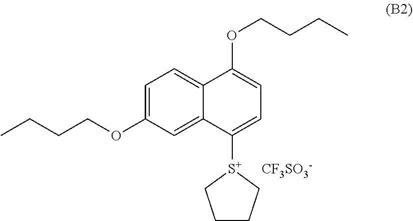

D1: Compound having a structure represented by the following formula (D1)

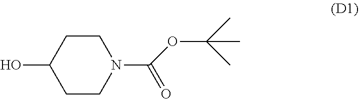

D2: Compound having a structure represented by the following formula (D2)

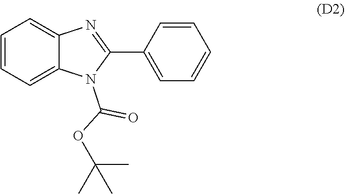 [SMILES: CC(C)(C)OC(=O)n1c(-c2ccccc2)nc2ccccc21]

E1: “NBX-15” (product name) manufactured by Neos Co., Ltd.

C1: γ-Butyrolactone

C2: Propyleneglycol monomethyl ether acetate

TABLE 2

| | | | | | | | | | Comparative | Comparative | Comparative | Comparative |
|---|---|---|---|---|---|---|---|---|---|---|---|---|
| | Exam- | Exam- | Exam- | Exam- | Exam- | Exam- | Exam- | Exam- | Exam- | Exam- | Exam- | Exam- |
| | ple 1A | ple 2A | ple 3A | ple 4A | ple 5A | ple 6A | ple 7A | ple 8A | ple 1A | ple 2A | ple 3A | ple 4A |
| A1 | 100 | 100 | 100 | | | | | | | | | |
| A2 | | | | 100 | | | | | | | | |
| A3 | | | | | 100 | | | | | | | |
| A4 | | | | | | 100 | | | | | | |
| A5 | | | | | | | 100 | | | | | |
| A6 | | | | | | | | 100 | | | | |
| RA1 | | | | | | | | | 100 | | | |
| RA2 | | | | | | | | | | 100 | | |
| RA3 | | | | | | | | | | | 100 | |
| RA4 | | | | | | | | | | | | 100 |
| B1 | 1 | | 1 | 1 | 1 | 1 | 1 | 1 | 1 | 1 | 1 | 1 |
| B2 | | 3 | | | | | | | | | | |
| D1 | | | 2 | | | | | | | | | |
| D2 | 0.2 | 1 | | 0.2 | 0.2 | 0.2 | 0.2 | 0.2 | 0.2 | 0.2 | 0.2 | 0.2 |
| E1 | 0.1 | 0.01 | 0.01 | 0.1 | 0.1 | 0.1 | 0.1 | 0.1 | 0.1 | 0.1 | 0.1 | 0.1 |
| C1 | | 10 | 10 | | | | | | | | | |
| C2 | 160 | 160 | 160 | 160 | 160 | 160 | 160 | 160 | 160 | 160 | 160 | 160 |

<Shape evaluation after EBR>

### Experimental Examples 1A to 8A and Comparative Experimental Examples 1A to 4A

Fifteen cubic centimeters (15 cc) of each of the photosensitive resin compositions of Examples 1A to 8A and Comparative Examples 1A to 4A was dropped on a 12-inch silicon wafer, and an EBR processing with a width of 5 mm was performed by spin coating (at a maximum rotation speed of 600 rpm for 60 seconds) using “CLEAN TRACK ACT12” (device name) manufactured by Tokyo Electron Ltd. while back rinsing was performed, thereby forming a coating of each of the photosensitive resin compositions of Examples 1A to 8A and Comparative Examples 1A to 4A. Three kinds of EBR solvents were used for the EBR processing: a mixed solvent containing 60% by mass of propyleneglycol monomethyl ether and 40% by mass of propyleneglycol monomethyl ether acetate (hereinafter, referred to as “EBR solvent A”); a solvent consisting of propyleneglycol monomethyl ether acetate (hereinafter, referred to as “EBR solvent B”); and a solvent consisting of ethyl lactate (hereinafter, referred to as “EBR solvent C”). The state of the peripheral edge of the 12-inch silicon wafer after the EBR processing with each EBR solvent was confirmed with a microscope and evaluated according to the following criteria. The evaluation results are indicated in Table 3 below.

A: There was no undissolved coating on the peripheral edge of the 12-inch silicon wafer.

B: The area of the undissolved coating on the peripheral edge of the 12-inch silicon wafer was greater than 0% and 50% or less relative to the total area of the coating to be removed.

C: The area of the undissolved coating on the peripheral edge of the 12-inch silicon wafer was greater than 50% relative to the total area of the coating to be removed.

TABLE 3

| | Shape after EBR | | |
|---|---|---|---|
| | EPR | EPR | EPR |
| | solvent A | solvent B | solvent C |
| Experimental Example 1A | A | A | A |
| Experimental Example 2A | A | A | A |
| Experimental Example 3A | A | A | A |
| Experimental Example 4A | A | A | A |
| Experimental Example 5A | A | A | A |
| Experimental Example 6A | A | A | A |
| Experimental Example 7A | A | A | A |
| Experimental Example 8A | A | A | A |
| Comparative Experimental | B | C | C |
| Example 1A | | | |
| Comparative Experimental | B | C | C |
| Example 2A | | | |
| Comparative Experimental | B | B | A |
| Example 3A | | | |
| Comparative Experimental | B | C | B |
| Example 4A | | | |

### <Formation of Resist Pattern>

Examples 1B to 8B and Comparative Examples 1B to 4B (Formation of resist pattern)

The photosensitive resin compositions of Examples 1A to 8A and Comparative Examples 1A to 4A were each applied onto a copper sputtered film provided on a silicon wafer substrate using a spin coater, and heated at a temperature of 120° C. for 300 seconds using a hot plate to form a coating having a thickness of 20 μm. The coating was exposed to light through a pattern mask using a stepper “NSR-i10D” (model name) manufactured by Nikon Corporation. The exposed coating was heated at a temperature of 90° C. for 180 seconds and then immersed in 2.38% by mass of an aqueous tetramethylammonium hydroxide solution for 180 seconds for development. Then, it was washed with running water and blown with nitrogen to form each of resist patterns (line/space=1/1) of Examples 1B to 8B and Comparative Examples 1B to 4B on the substrate. The substrate on which the resist pattern was formed is referred to as “patterning substrate”. Using this patterning substrate, the “resolution” and “plating solution resistance” were evaluated by the methods which will be indicated below.

### “Resolution”

The patterning substrate was observed with a scanning electron microscope, and the resolution was evaluated according to the following criteria. The evaluation results are indicated in Table 4 below.

A: A resist pattern with a line width of 5 μm could be resolved.

B: A resist pattern with a line width of 5 μm could not be resolved, but a resist pattern with a line width of 10 μm could be resolved.

C: A resist pattern with a line width of 10 μm could not be resolved, but a resist pattern with a line width of 15 μm could be resolved.

### “Plating Solution Resistance (Swelling Resistance)”

The patterning substrate was immersed in 1 L of a copper plating solution “MICROFAB Cu300” (product name) manufactured by EEJA at a temperature of 25° C. for 15 minutes, and the resist pattern shapes before and after the immersion were observed with an optical microscope and a scanning electron microscope to evaluate the plating solution resistance (swelling resistance) according to the following criteria. The evaluation results are indicated in Table 4.

A: The reduction rate of the line width of the resist pattern before and after immersion was 5% or less.

A: The reduction rate of the line width of the resist pattern before and after immersion was greater than 5% or less and 10% or less.

C: The reduction rate of the line width of the resist pattern before and after immersion was greater than 10%.

TABLE 4

| | | Plating solution |
|---|---|---|
| | | resistance |
| | Resolution | (Swelling resistance) |
| EXAMPLE 1B | A | A |
| EXAMPLE 2B | A | A |
| EXAMPLE 3B | A | A |
| EXAMPLE 4B | A | A |
| EXAMPLE 5B | A | A |
| EXAMPLE 6B | A | A |
| EXAMPLE 7B | A | A |
| EXAMPLE 8B | A | A |
| COMPARATIVE EXAMPLE 1B | C | A |
| COMPARATIVE EXAMPLE 2B | C | B |
| COMPARATIVE EXAMPLE 3B | B | C |
| COMPARATIVE EXAMPLE 4B | C | A |

### <Production of Plated Formed Article>

### Example 1C

The patterning substrate of Example 1B was subjected to ashing treatment with oxygen plasma (output: 100 W, oxygen flow rate: 100 milliliters, and treatment time: 60 seconds). The patterning substrate after the ashing treatment was immersed in 1 L of a copper plating solution “MICROFAB Cu300” (product name) manufactured by EEJA, and subjected to electrolytic plating at a plating bath set to a temperature of 25° C. and a current density of 3A/dm² for 15 minutes, thereby producing a plated formed article. This plated formed article had a good shape.

1. A photosensitive resin composition comprising:
a polymer (A) having a structural unit (a1) represented by the following formula (a1), a structural unit (a2) represented by the following formula (a2), and a structural unit (a3) represented by the following formula (a3); and
a photoacid generator (B): 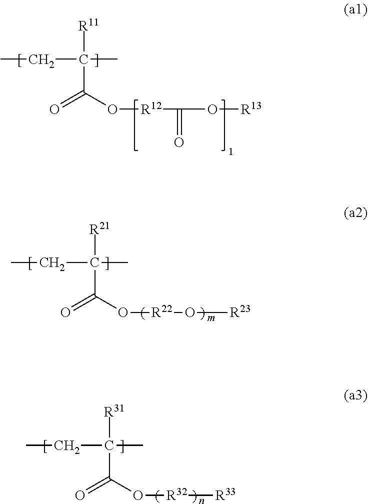
wherein in the formulae (a1) to (a3), R¹¹, R²¹ , and R³¹ each independently represent a hydrogen atom, a substituted or non-substituted alkyl group having 1 to 10 carbon atom or a halogen atom; R¹² and R³² each independently represent a divalent organic group;
R²² represents a substituted or non-substituted alkanediyl group having 2 to 10 carbon atoms;
R¹³ represents an acid dissociable group having an alicyclic structure; R²³ represents an alkyl group having 1 to 10 carbon atoms; R³³ represents a hydroxyaryl group; and 1, m and n each independently represent an integer from 0 to 10.

2. The photosensitive resin composition according to claim 1, wherein a content ratio of the structural unit (a2) contained in the polymer (A) is in a range from 1% to 50% by mol when a total of all the structural units constituting the polymer (A) is 100% by mol.

3. The photosensitive resin composition according to claim 1, wherein a total content ratio of the structural units (a1) and (a3) contained in the polymer (A) is in a range from 50% to 95% by mol when a total of all the structural units constituting the polymer (A) is 100% by mol.

4. The photosensitive resin composition according to claim 1, wherein the R¹³ is an acid dissociable group represented by the following formula (1): 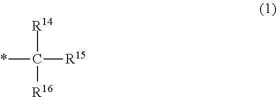
wherein in the formula (1), R¹⁴ and R¹⁵ form an alicyclic structure together with the bonded carbon atom; R¹⁶ represents a substituted or non-substituted alkyl group having 1 to 10 carbon atoms; and * represents a bonded hand.

5. The photosensitive resin composition according to claim 1, wherein a total content ratio of the structural units (a1) to (a3) contained in the polymer (A) is in a range from 51% to 100% by mol when a total of all the structural units constituting the polymer (A) is 100% by mol.

6. The photosensitive resin composition according to claim 1, wherein a content of the photoacid generator (B) included in the photosensitive resin composition is in a range from 0.1 to 20 parts by mass based on 100 parts by mass of the polymer (A).

7. The photosensitive resin composition according to claim 1, further comprising an organic solvent (C), wherein a content ratio of the organic solvent (C) included in the photosensitive resin composition is an amount such that a solid content concentration is in a range from 10% to 60% by mass.

8. The photosensitive resin composition according to claim 1, which is used for manufacturing a plated formed article.

9. A method for forming a resist pattern, comprising:
a step (1) of applying the photosensitive resin composition according to claim 1 onto a substrate to form a resin coat;
a step (2) of exposing the resin coat to light; and
a step (3) of developing the resin coat after the exposure.

10. A method for manufacturing a plated formed article, comprising a step (4) of performing a plating using a resist pattern formed by the resist pattern forming method according to claim 9 as a mask.

11. The method for manufacturing a plated formed article according to claim 10, wherein the plating is at least one selected from a copper plating and a nickel plating.

12. A semiconductor device comprising a plated formed article obtained by the plated formed article manufacturing method according to claim 10.

13. A semiconductor device comprising a plated formed article obtained by the plated formed article manufacturing method according to claim 11.

14. The photosensitive resin composition according to claim 2, wherein a total content ratio of the structural units (a1) and (a3) contained in the polymer (A) is in a range from 50% to 95% by mol when a total of all the structural units constituting the polymer (A) is 100% by mol.

15. The photosensitive resin composition according to claim 2, wherein the R¹³ is an acid dissociable group represented by the following formula (1): 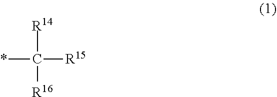
wherein in the formula (1), R¹⁴ and R¹⁵ form an alicyclic structure together with the bonded carbon atom; R¹⁶represents a substituted or non-substituted alkyl group having 1 to 10 carbon atoms; and * represents a bonded hand.

16. The photosensitive resin composition according to claim 2, wherein a total content ratio of the structural units (a1) to (a3) contained in the polymer (A) is in a range from 51% to 100% by mol when a total of all the structural units constituting the polymer (A) is 100% by mol.

17. The photosensitive resin composition according to claim 2, wherein a content of the photoacid generator (B) included in the photosensitive resin composition is in a range from 0.1 to 20 parts by mass based on 100 parts by mass of the polymer (A).

18. The photosensitive resin composition according to claim 2, further comprising an organic solvent (C), wherein a content ratio of the organic solvent (C) included in the photosensitive resin composition is an amount such that a solid content concentration is in a range from 10% to 60% by mass.

19. The photosensitive resin composition according to claim 2, which is used for manufacturing a plated formed article.

20. A method for forming a resist pattern, comprising:
a step (1) of applying the photosensitive resin composition according to claim 2 onto a substrate to form a resin coat;
a step (2) of exposing the resin coat to light; and
a step (3) of developing the resin coat after the exposure.

21. A method for manufacturing a plated formed article, comprising a step (4) of performing a plating using a resist pattern formed by the resist pattern forming method according to claim 20 as a mask.

22. The method for manufacturing a plated formed article according to claim 21, wherein the plating is at least one selected from a copper plating and a nickel plating.

23. A semiconductor device comprising a plated formed article obtained by the plated formed article manufacturing method according to claim 21.

24. A semiconductor device comprising a plated formed article obtained by the plated formed article manufacturing method according to claim 22.
